(19) United States
(12) Patent Application Publication
(10) Pub. No.: US 2008/0305573 A1
(43) Pub. Date: Dec. 11, 2008

(54) Photovoltaically Active Semiconductor Material and Photovoltaic Cell

(75) Inventor: Hans-Josef Sterzel, Dannstadt-Schauernheim (DE)

Correspondence Address: OBLON, SPIVAK, MCCLELLAND MAIER & NEUSTADT, P.C., 1940 DUKE STREET, ALEXANDRIA, VA, 22314, US

(73) Assignee: BASF SE, Ludwigshafen (DE)

(21) Appl. No.: 12/159,954

(22) PCT Filed: Dec. 18, 2006
(86) PCT No.: PCT/EP2006/069808

§ 371 Date: Jul. 2, 2008

(30) Foreign Application Priority Data
Jan. 3, 2006 (EP) 06100036.0

(51) Int. Cl. H01L 21/00; H01L 31/00

(52) U.S. Cl. 438/84; 136/256; 136/255; 257/E21.001

(57) ABSTRACT

The invention relates to a photovoltaically active semiconductor material and a photovoltaic cell comprising a photovoltaically active semiconductor material, wherein the photovoltaically active semiconductor material contains a crystal lattice composed of zinc telluride and, in the zinc telluride crystal lattice, ZnTe is substituted by—0.01 to 10 mol % CoTe, —0 to 10 mol % Cu₂Te, Cu₃Te or CuTe and —0 to 30 mol % of at least one compound selected from the group MgTe and MnTe, and wherein, in the zinc telluride crystal lattice Te is substituted by—0.1 to 30 mol % oxygen. The photovoltaic cell furthermore has a rear contact composed of a rear contact material that forms a metal telluride with tellurium.

The invention relates to photovoltaic cells and the photovoltaically active semiconductor material comprised therein.

Photovoltaically active materials are semiconductors which convert light into electric energy. The underlying principles have been known for a long time and are utilized industrially. The majority of industrially utilized solar cells are based on crystalline silicon (single crystal or polycrystalline). In a boundary layer between p- and n-conducting silicon, incident photons excite electrons of the semiconductor so that they are lifted from the valence band into the conduction band.

The height of the energy gap between the valence band and the conduction band limits the maximum possible efficiency of the solar cell. In the case of silicon, this is about 30% for irradiation with sunlight. On the other hand, an efficiency of about 15% is achieved in practice because part of the charge carriers recombine by means of various processes and are thus not able to be utilized.

DE 102 23 744 A1 discloses alternative photovoltaically active materials and photovoltaic cells comprising these, which display the efficiency-reducing loss mechanisms to a reduced degree.

With an energy gap of about 1.1 eV, silicon has a quite good value for utilization. Although decreasing the size of the energy gap results in more charge carriers being transported into the conduction band, the cell voltage becomes lower. Correspondingly, although higher cell voltages are achieved at large energy gaps, lower usable currents are available because fewer photons are present for excitation.

Many arrangements such as the arrangement of semiconductors having various energy gaps in series in tandem cells have been proposed in order to achieve higher efficiencies. However, these are difficult to realize economically because of their complex structure.

A new concept comprises generating an intermediate level within the energy gap (up-conversion). This concept is described, for example, in the Proceedings of the 14th Workshop on Quantum Solar Energy Conversion-Quantasol 2002, Mar., 17-23, 2002, Rauris, Salzburg, Austria, “Improving solar cells efficiencies by the up-conversion”, T I. Trupke, M. A. Green, P. Würfel or “Increasing the Efficiency of Ideal Solar Cells by Photon Induced Transitions at intermediate Levels”, A. Luque and A. Marti, Phys. Rev. Letters, Vol. 78, No. 26, June 1997, 5014-5017. A band gap of 1.995 eV and an energy of the intermediate level of 0.713 eV gives a calculated maximum efficiency of 63.17%.

Such intermediate levels have been confirmed spectroscopically for, for example, the system Cd_{1-y}Mn_{y}OₓTe₁₋ₓ or Zn₁₋ₓMnₓO_{y}Te_{1-y}. This is described in “Band anticrossing in group II—OₓVI₁₋ₓ highly mismatched alloys: Cd_{1-y}Mn_{y}OₓTe₁₋ₓ quaternaries synthesized by O ion implantation”, W. Walukiewicz et al., Appl. Phys. Letters, Vol. 80, No. 9, March 2002, 1571-1573, and in “Synthesis and optical properties of II—O—VI highly mismatched alloys”, W. Walukiewicz et al., J. Appl. Phys. Vol. 95, No. 11, June 2004, 6232-6238. In these studies, the desired intermediate energy level in the band gap is raised by replacing part of the tellurium anions in the anion lattice by the significantly more electronegative oxygen ion. Tellurium was in this case replaced by oxygen by means of ion implantation in thin films. A significant disadvantage of this class of substances is that the solubility of oxygen in the semiconductor is extremely low. In the above-mentioned publication in Appl. Phys. Letters, Volume 80, a value of 10¹⁷ O/cm³ is given. As a consequence, the compounds Zn₁₋ₓMnₓTe_{1-y}O_{y} with y greater than 0.0001, for example, are not thermodynamically stable.

The corresponding patent application WO 2005/055285 A2 therefore proposes to bombard thin films layers with O⁺-ions and to subsequently melt the oxygen with a pulsed KrF-laser within about 38 ns, in order to “anchor” the oxygen in the crystal lattice (pulse laser melting). Tellurides of the composition Zn_{0.88}Mn_{0.12}Te are implanted there with 3.3 At-% O⁺. The material obtained therewith is terminally stable up to 350° C.

However, WO 2005/055285 A2 does not show the chemical process of the implantation of the O⁺-ions. According to

Zn_{0.88}Mn_{0.12}Te+O⁺→Zn_{0.88}Mn_{0.12}Te₁₋ₓOₓ+Te⁺,

(positive) Te-ions should be released, which, from a chemical point of view, is hardly possible. It is not stated, whether tellurium is released and where it remains. It is solely stated that a part of ZnTe is replaced by MnTe, since the implantation of oxygen should be promoted by the Mn-concentration. For practice, the given instructions are incomplete and hardly lead, if at all, to the aim of more efficient photovoltaic cells with intermediate band.

It is the object of the present invention to provide a photovoltaically active semiconductor material for a photovoltaic cell which has a high efficiency and a high performance. A further object of the present invention is, in particular, to provide an alternative, thermodynamically stable, photovoltaically active semiconductor material which comprises an intermediate level in the energy gap.

This object is achieved according to the invention by a photovoltaically active semiconductor material comprising a crystal lattice of zinc telluride, wherein ZnTe in the zinc telluride crystal lattice is replaced by 0.01-10 mol %, preferably 0.1-10 mol %, in particular preferred by 0.03-5 mol %, more particularly preferred by 0.5-3 mol % CoTe, whereby, in the zinc telluride lattice, Te is substituted by 0.01-30 mol %, and preferably by 0.5-10 mol % oxygen.

Very surprisingly, it has been found that oxygen can be integrated into the zinc telluride lattice, if this comprises cobalt telluride. Thereby, the amount of cobalt in zinc telluride is preferably 0.01 to 10 At-%, and more preferably 0.5 to 3 At-%. A zinc telluride with the corresponding amount of cobalt incorporates molecular oxygen, whereby elemental tellurium is released according to formula (I).

Zn₁₋ₓCoₓTe+y/2O₂→Zn₁₋ₓCoₓTe_{1-y}O_{y}+yTe (I).

Thereby, no zinc oxide is formed.

This reaction is promoted by a metallic layer of a material, which forms, together with tellurium, a metal telluride, with which the semiconductor material is in contact, such that the material of the metallic layer, together with the telluride released in the semiconductor material upon substitution by oxygen, forms telluride. As an example, the metallic layer can be a metallic rear contact of a photovoltaic cell, whereby the metal of the rear contact forms, together with the released tellurium, tellurides in an intermediate layer. As metals in the metallic layer, in particular in the rear contact, are Ag, Zn, Mo, W, Cr, Cu, Co, or Ni are particularly preferred. More preferably, a metallic layer containing zinc is used.

In view of such an additional function of the rear contact of the photovoltaic cell, it is important that the formed tellurides provide a high electrical conductivity (metallic or p-conducting) in order not to increase the cell resistance substantially. According to the concentration gradient produced by the reaction at the metal boundary layer, the tellurium diffuses in the semiconductor material in the direction of the rear contact. This is required since elemental tellurium absorbs practically all incident light due to the low band gap of 0.2 eV, which would render the photovoltaic cell unusable.

According to its nature to form a drain for tellurium, the kind of the metallic layer, in particular of the rear contact, is important for the integration of oxygen in the zinc telluride lattice. The more reactive the metal of the metallic layer (for example of the rear contact) is in relation to the elemental tellurium at the given deposition temperature or oxidation temperature, the more oxygen is integrated into the zinc telluride lattice. In this way, the kind of the metallic layer (the rear contact) determines the formation and arrangement of the intermediate band in the band gap.

The preferred temperatures at which the reaction according to formula (I) is provided, are as follows. The preferred temperature lies in the range of room temperature up to 400° C., particularly preferred in the range of 250° C. to 350° C. The oxygen partial pressure can be in the range of 0.001 Pa to 10⁵ Pa. Thus, as an example, air at 10⁵ Pa can be used. The reaction time is preferably 0.1 to 100 min, more preferably 1 to 20 min.

According to one embodiment of the present invention, ZnTe in the zinc telluride in the crystal lattice of the photovoltaic active semiconductor materials according to the invention is substituted by 0 to 30 mol % of at least one compound selected from the group of MgTe and MnTe.

In the context of this invention, the formulation of x to y mol % (e.g. with x=0 and y=10) of at least one compound selected from the group, that, in case of two or more compounds of the group, x to y mol % of each of the compounds can be comprised.

By the integration of magnesium and/or manganese to the ZnTe lattice, the total bandwidth is enlarged. The enlargement is at about 0.1 eV/10 mol % MgTe, respectively at about 0.043 eV/10 mol % MnTe. The bandwidth of ZnTe has a value of about 2.25 eV. A zinc telluride semiconductor in which 50 mol % are substituted by MgTe or MnTe, provides a width of the band gap of about 2.8 eV or of about 2.47 eV, respectively. For the semiconductor material according to the invention, an enlargement of a band gap by magnesium or manganese is possible. However, the photovoltaic active semiconductor material according to the invention is preferred without band gap enlargement (0 mol % of ZnTe substituted by MgTe and MnTe).

According to a preferred embodiment of the present invention, ZnTe in the zinc telluride lattice of the photovoltaic active semiconductor material is substituted by 0 to 10 mol %, preferably by 0.5 to 10 mol %, Cu₂Te, Cu₃Te, or CuTe. According to a more preferred embodiment of the present invention, Te in the zinc telluride crystal lattice of the photovoltaic active semiconductor material is substituted by 0 to 10 mol %, preferably by 0.5 to 10 mol % N and/or P. The electrical conductivity of zinc telluride is increased by doping with copper, phosphorus, or nitrogen. This also applies for the photovoltaic active semiconductor material according to the invention. The increase of the electrical activity is advantageous for the use of the photovoltaic active semiconductor material in a photovoltaic cell.

Further, the invention relates to a semiconductor material with a crystal lattice of zinc telluride, wherein ZnTe in the zinc telluride lattice is substituted by:
0.1 to 10 mol % CoTe,
0 to 10 mol % Cu₂Te, Cu₃Te or CuTe, and
0 to 30 mol % of at least one compound selected from the group MgTe and MnTe.

In this semiconductor material, tellurium can be replaced by 0 to 30 mol % oxygen for manufacturing of a photovoltaic active semiconductor material according to the invention.

The invention further relates to a photovoltaic cell comprising the photovoltaic active semiconductor material according to the invention. Preferably, a photovoltaic cell with a photovoltaic active semiconductor material is provided, wherein the photovoltaic active semiconductor material comprises a crystal lattice of zinc telluride, the ZnTe in the zinc telluride crystal lattice being substituted by:
0.01 to 10 mol %, preferably 0.1 to 10 mol %, more preferably 0.3 to mol %, particularly more preferred 0.5 to 3 mol % CoTe,
0 to 10 mol % Cu₂Te, Cu₃Te, or CuTe, and
0 to 30 mol % of at least one compound selected from the group MgTe and MnTe,
   wherein Te is substituted by
0.1 to 30 mol %, preferably 0.5 to 10 mol % oxygen
   wherein the photovoltaic cell further comprises a rear contact of a rear contact material forming a metal telluride with tellurium. The function of the rear contact is described above.

The photovoltaic cell of the invention has the advantage that the inventive photovoltaically active semiconductor material used is stable up to 400° C. Furthermore, the photovoltaic cells of the invention have high efficiencies of greater than 15%, since an intermediate level is generated in the energy gap of the photovoltaically active semiconductor material. Without an intermediate level, only photons, electrons or charge carriers which have at least the energy of the energy gap can go up from the valence band into the conduction band. Photons of higher energy also contribute to the efficiency, with the excess of energy over the band gap being lost as heat. In the presence of the intermediate level which is present in the semiconductor material used for the present invention and can be partly occupied, more photons can contribute to excitation.

The photovoltaic cell of the invention preferably has a structure comprising a p-conducting absorber layer of the photovoltaically active semiconductor material of the invention, the absorber layer being located on the material of the rear contact. This absorber layer of the p-conducting semiconductor material is adjoined by an n-conducting contact layer which, as a windows, absorbs virtually no incident light, preferably an n-conducting transparent layer comprising at least one semiconductor material selected from the group consisting of indium-tin oxide, fluorine-doped tin oxide, antimony-doped, gallium-doped, indium-doped or aluminum-doped zinc oxide. Incident light generates a positive charge and a negative charge in the p-conducting semiconductor layer. The holes diffuse in the p-region to the rear contact. At the interface between the p-conducting absorber according to the invention and the rear contact, they recombine with electrons leaving the rear contact. The electrons diffuse through the n-conducting window layer to the drains, through the circuit and then into the rear contact.

The material of the rear contact, onto which the absorber layer is arranged, preferably comprises at least one element selected from the group consisting of Cu, Ag, Zn, Cr, Mo, W, Co, and Ni, and more preferably Zn. It is known that in particular aluminum-doped zinc oxide is very suitable as a window layer for zinc telluride (“Studies of sputtered ZnTe films as interlayer for the CdTe thin film solar cell”, B. Späth, J. Fritsche, F. Säuberlich, A. Klein, W. Jaegermann, Thin Solid Films 480-481 (2005) 204 to 207).

In a preferred embodiment of the present invention, photovoltaic cells according to the invention are provided as photovoltaic cells with intermediate band, wherein the absorber is provided according to the composition Zn_{1-x-z}CoₓMe_{z}Te_{1-y}O_{y}, with x=0.001 to 0.05; z=0 to 0.4; y=0.001 to 0.3, and Me=Mg, Mn, and/or Cu.

In a preferred embodiment of the photovoltaic cell of the invention, it comprises an electrically conductive substrate, a p-layer of the inventive photovoltaically active semiconductor material having a thickness of from 0.1 to 20 μm, preferably from 0.1 to 10 μm, particularly preferably from 0.3 to 3 μm, and an n-layer of an n-conducting semiconductor material having a thickness of from 0.1 to 20 μm, preferably from 0.1 to 10 μm, particularly preferably from 0.3 to 3 μm. The substrate is preferably a sheet of glass coated with an electrically conductive material, a flexible metal foil or a flexible metal sheet. Combining a flexible substrate with thin photovoltaically active layers gives the advantage that complicated and therefore expensive supports do not have to be used for mounting the solar modules comprising the photovoltaic cells of the invention. The flexibility makes warping possible, so that very simple and inexpensive support constructions which do not have to be stiff and warping-resistant can be used. As a preferred flexible substrate, in the present invention a sheet of stainless steel can be used.

The invention further provides a sputtering target comprising a zinc telluride semiconductor material in which ZnTe is replaced by
from 0.01 to 10 mol %, preferably 0.1 to 10 mol %, more preferably 0.3 to 5 mol %, most preferably 0.5 to 3 mol % CoTe,
from 0 to 10 mol % of Cu₂Te, Cu₃Te or CuTe and
from 0 to 30 mol % of at least one compound selected from the group consisting of MgTe and MnTe.

This sputtering target can be employed for sputtering a semiconductor material layer of the photovoltaic semiconductor material of the invention, with the composition of the layer being able to deviate from the composition of the sputtering target, for example because of differing volatilities of the elements comprised in the sputtering target. Furthermore, further sputtering targets, for example cosputtering targets composed of copper, can be used in sputtering using the sputtering target of the invention and/or further elements can be introduced into the sputtered layer by reactive sputtering.

The invention further provides a process for producing the photovoltaically active semiconductor material of the invention and/or a photovoltaic cell according to the invention, in which a layer of the photovoltaically active semiconductor material of the invention is produced on a layer of material, which forms a metal telluride with tellurium by means of at least one deposition process selected from the group consisting of sputtering, electrochemical deposition, electroless deposition, physical vapor deposition (vaporization), chemical vapor deposition and laser ablation. Generally, each method of manufacturing a photovoltaic active semiconductor material known to a person skilled in the art can be used.

Preferably, the layer of the photovoltaically active semiconductor material is used according to the inventive method for substituting tellurium in the crystal lattice of the semiconductor materials by oxygen in an oxygen-containing atmosphere.

The resulting layer of the photovoltaically active semiconductor material preferably has a thickness of from 0.1 to 20 μm, preferably from 0.1 to 10 μm, particularly preferably from 0.3 to 3 μm. This layer is produced by means of at least one deposition process selected from the group consisting of sputtering, electrochemical deposition, electroless deposition, physical vapor deposition, chemical vapor deposition or laser ablation.

The term sputtering refers to a process in which clusters comprising from about 10 to 10 000 atoms are knocked out of a sputtering target serving as electrode by means of accelerated ions and the knocked-out material is deposited on a substrate. The layers of the photovoltaically active semiconductor material of the invention which are produced by the process of the invention are particularly preferably produced by sputtering because sputtered layers are of better quality. However, the deposition of zinc and cobalt and, if appropriate, Mg and/or Mn and/or Cu on a suitable substrate and subsequent reaction with a Te vapor at temperatures less than 400° C. in the presence of hydrogen is also possible. Furthermore, electrochemical deposition of ZnTe to produce a layer and subsequent doping of this layer with cobalt to produce a photovoltaically active semiconductor material according to the invention is also suitable.

Particular preference is given to introducing the cobalt during the synthesis of the zinc telluride in evacuated fused silica vessels. Here, zinc, tellurium and cobalt or mixtures of titanium and cobalt and, if appropriate, magnesium and/or manganese and/or copper are introduced into the fused silica vessel, the fused silica vessel is evacuated and flame sealed under vacuum. The fused silica vessel is then heated in a furnace, firstly rapidly to about 400° C. because no reaction takes place below the melting points of Zn and Te. The temperature is then increased more slowly at rates of from 20 to 100° C./h to from 800 to 1300° C., preferably to from 1100 to 1200° C. Formation of the solid state microstructure takes place at this temperature. The time necessary for this is from 1 to 100 hours, preferably from 5 to 50 hours. Cooling then takes place. The contents of the fused silica vessel are, in the absence of moisture, broken up to particle sizes of from 0.1 to 1 mm and these particles are then, for example, comminuted to particle sizes of from 1 to 30 μm, preferably from 2 to 20 μm, in a ball mill. Sputtering targets are produced from the resulting powder by hot pressing at from 300 to 1200° C., preferably from 400 to 700° C., and pressures of from 5 to 500 MPa, preferably from 20 to 200 MPa. The pressing times are from 0.2 to 10 hours, preferably from 1 to 3 hours.

In a preferred embodiment of the process of the invention, the photovoltaically active semiconductor material is produced by sputtering using a sputtering target comprising a photovoltaically active semiconductor material which comprises a crystal lattice of zinc telluride in which ZnTe is replaced by
from 0.01 to 10 mol %, preferably 0.1 to 10 mol %, more preferably 0.3-5 mol %, most preferably 0.5-3 mol % CoTe,
from 0 to 10 mol % of Cu₂Te, Cu₃Te or CuTe and
from 0 to 30 mol % of at least one compound selected from the group consisting of MgTe and MnTe.

In a further preferred embodiment of the process of the invention, nitrogen or phosphorus is introduced into the layer of the photovoltaically active semiconductor material by reactive sputtering in a nitrogen-, ammonia- or phosphine-comprising sputtering atmosphere. The proportion of nitrogen or phosphorus (to increase the electrical conductivity of the photovoltaically active semiconductor material of the invention) is determined by the sputtering parameters. Particularly preferred, nitrogen is introduced into the layer of the photovoltaically active material by reactive sputtering. (R. G. Bohn et. al: RF sputtered films of Cu-doped and N-doped ZnTe, 1994, IEEE, Vol. 1, pages 354-356)

In an embodiment of the process of the invention, copper is introduced into the layer of the photovoltaically active semiconductor material by cosputtering of a copper target with a target comprising the photovoltaically active semiconductor material of the invention. Copper, of which, for example, amounts of from 0.5 to 10 mol % are able to increase the electrical conductivity of the photovoltaically active semiconductor material of the invention, can be applied by cosputtering of a copper target simultaneously with the sputtering of the Co-doped ZnTe. In the case of cosputtering, too, the proportion of copper is determined by the sputtering parameters. However, the copper can also be introduced at the beginning into the target composition. Here, for example, from 0.5 to 10 mol % of the zinc in the sputtering target is replaced by copper.

In a preferred embodiment of the process of the invention for producing the photovoltaically active semiconductor material of the invention and/or a photovoltaic cell according to the invention, a sputtering target comprising a crystal lattice of zinc telluride in which ZnTe is replaced by
from 0.01 to 10 mol %, preferably 0.1 to 10 mol %, more preferably 0.3-5 mol %, most preferably 0.5-3 mol %,
from 0 to 10 mol % of Cu₂Te, Cu₃Te and CuTe and
from 0 to 30 mol % of at least one compound selected from the group consisting of MgTe and MnTe, is produced by means of the steps
a) reaction of Zn, Te and Co and, if appropriate, at least one element selected from the group consisting of Mg and Mn and, if appropriate, Cu in an evacuated fused silica tube at from 800° C. to 1300° C., preferably from 1100 to 1200° C., for a period of from 1 to 100 hours, preferably from 5 to 50 hours, to provide a material,
b) milling of the material after cooling with substantial exclusion of oxygen and water to give a powder having particle sizes of from 1 μm 10 to 30 μm, preferably from 2 to 20 μm, and
c) hot pressing of the powder at temperatures of from 300° C. to 1200° C., preferably from 400° C. to 700° C., at pressures of from 5 to 500 MPa, preferably from 20 to 200 MPa, for pressing times of from 0.2 to 10 hours, preferably from 1 to 3 hours, to provide the sputtering target.

The sputtering target produced in this way is then used for sputtering a layer consisting of the photovoltaically active semiconductor material of the invention, or in which layer Te is replaced by O for producing the photovoltaically active semiconductor material of the invention, such that the layer can be used as absorber layer in a photovoltaic cell according to the invention.

<G> The substitution of Te by O in a semiconductor material with a crystal lattice of zinc telluride in which ZnTe is substituted by 0.01 to 10 mol %, preferably 0.1 to 10 mol %, more preferably 0.3 to 5 mol % and most preferably 0.5 to 3 mol % CoTe, can be provided according to the invention in different ways.

According to a preferred embodiment of the present invention, a production of a layer of a semiconductor material with a crystal lattice of zink telluride, in which ZnTe is substituted by 0.01 to 10 mol % CoTe, 0 to 10 mol % Co₂Te, Co₃Te or CoTe, and 0 to 30 mol % of a compound selected from the group consisting of MgTe and MnTe. This layer is maintained at a temperature between room temperature and 400° C., preferably between 250 and 350° C. at an oxygen partial pressure of 0.01 Pa to 10⁵ Pa for a duration between 0.1 and 100 min for substituting of tellurium in the crystal lattice of the semiconductor material by 0.1 to 30 mol % oxygen.

According to another embodiment of the method of the invention, oxygen is introduced into the layer of the photovoltaically active semiconductor material according to the invention by sputtering in an oxygen-containing sputter atmosphere.

In order to heat the semiconductor material for substituting Te by O, it is possible, as an example, to heat an arrangement comprising a substrate, a rear contact and an absorber in air by thermal contact with a heated surface or by heating from the rear side, or to provide the arrangement at the desired temperature by heat radiation, for example, by means of a halogen lamp. The temperature is the most critical parameter of the reaction parameters temperature, oxygen partial pressure and time duration. The temperature should lie between room temperature and 400° C., preferably in the range of 250 to 350° C. The exchange of tellurium for oxygen is rapid is carried out rapidly at these temperatures. The duration is, in essence, necessary for providing a diffusion of the elemental tellurium through the ZnTe-layer to the metallic layer, for example, to the rear contact. This can also be provided by heating the arrangement after a short chemical reaction under inert gas, preferably argon. In this way, an eventually undesired high degree of substitution is inhibited. According to an embodiment of the inventive method, a layer of the photovoltaically active semiconductor material is provided subsequently after reaction conditions at which a substitution of tellurium in the crystal lattice of the semiconductor material by oxygen occurs, for a duration of between 0.1 and 10 minutes on a temperature between 250 and 350° C. in an inert atmosphere, in order to effect a diffusion of tellurium in the semiconductor material to the material, which forms a metal telluride with the tellurium.

However, it is also possible to accomplish the substitution reaction already during the application of the semiconductor material (the absorber layer), for example, by adding small amounts of oxygen to the sputter atmosphere—usually argon under a pressure of about 1 Pa—during a sputter process. The added amount of oxygen preferably lies between 0.01 and 5% and, more preferably, between 0.1 and 1%, in relation to the argon. This “reactive sputter process” is more economic than the separated oxidation, since one process step is omitted. Usually, the substrate is heated during the application of the semiconductor material onto temperatures of 200 to 350° C., in order to deposit an absorber layer which is as crystalline as possible. This temperature is used for the substitution reaction.

The semiconductor layer (the absorber layer) can also be applied by a method known by a person skilled in the art, and can be exposed to an oxygen-containing atmosphere before applying the window layer, in order to provide the substitution reaction. This is very advantageous, since window layers which are usually oxides, are often applied in oxygen-containing atmospheres in order to prevent any loss of oxygen in the window layer.

The invention is exemplified by use of the figure.

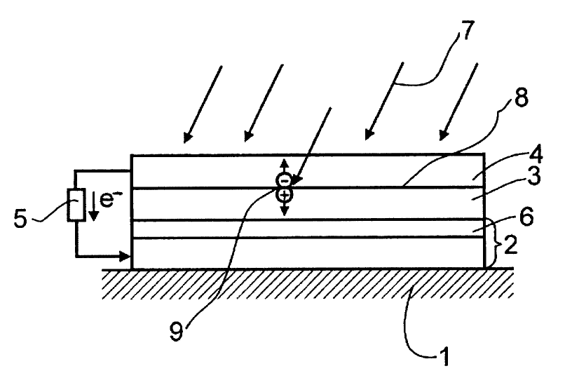

FIG. 1 shows the structure of an embodiment of a photovoltaic cell according to the invention, which comprises an absorber layer of a photovoltaically active semiconductor material according to the invention.

The photovoltaic cell shown in FIG. 1 comprises numerous layers, which are arranged on a substrate 1, for example made of glass. In the depicted embodiment, the rear layer 2 lies on the substrate 1. This rear contact 2 comprises a rear contact material, which can form metal telluride with tellurium. For example, the rear contact 2 is a rear contact of molybdenum, which is layered with zinc. On the rear contact 2, a p-conducting absorber layer 3 of the photovoltaically active semiconductor material according to the invention is arranged. In the zinc telluride crystal lattice of the semiconductor material of the absorber layer 3, ZnTe is substituted by 0.01 to 10 mol % CoTe, and Te is substituted by 0.1 to 30 mol % oxygen. On the p-conducting absorber layer 3, an n-conducting transparent layer 4 is arranged, which contains indium tin oxide, fluorine-doped tin oxide, antimony-doped zinc oxide, gallium-doped zinc oxide or aluminum-doped zinc oxide. The n-conducting layer 4 is connected to the rear contact 2 via a load 5, which is shown schematically.

In the course of the production of the p-conducting absorber layer, tellurium in the zinc telluride crystal lattice of the used semiconductor material is substituted by oxygen. The released tellurium diffuses in the absorber layer 3 in direction of the rear contact 2. The metal of the rear contact 2 forms, together with the tellurium, telluride in an intermediate layer 6. In this way, the absorption of incident light by the elemental tellurium is prevented.

Incident photons 7 produce free charge carriers (electron hole pairs 9) in the area of the p-n-junction 8. These are accelerated by the electrical field in the space charge region in different directions. The current produced thereby can be used by the load 5.

### EXAMPLES

The examples have been carried out with the composition Zn_{0.99}Co_{0.01}Te.

For this purpose, the elements which each had a purity of better than 99.99% were weighed into fused silica tubes, the residual moisture was removed by heating under reduced pressure and the tubes were flame sealed under reduced pressure.

In a slanting tube furnace, the tubes were heated from room temperature to 1200° C. over a period of 60 hours and the temperature was then maintained at 1200° C. for 10 hours. The furnace was then switched off and allowed to cool.

After cooling, the silica tubes have been opened under argon and the resulting telluride has been milled in an agate mortar into pieces of about 1 mm to 5 mm. Finally, the milled material has been brought into the milling jar of a planet sphere mill. The powder bulk has been perfused by n-octane, and, subsequently, the milling balls of stabilized zirconium dioxide with a diameter of 20 mm have been added. The volume portion of the milling spheres was about 60%. The milling jar has been closed under argon and the batch has been milled for 24 hours, whereby the telluride has been milled onto a particle size of 2 to 30 μm.

The milling balls have been separated and the n-octane has been distilled from the telluride powder under argon at temperatures up to 180° C.

The dried telluride powder has been brought into a graphite matrix of a hot press having an inner diameter of 2 inches (about 51 mm). The piston has been attached, the material has been heated to 600° C., and a pressure of 5000 Newton/cm has been applied subsequently. After cooling a grey disk with a thickness of 3 mm was obtained, which had a red shine.

The sputter target obtained thereby has been bonded onto a support plate of copper using indium, such that the actual sputter target has been provided.

For manufacturing different rear contacts, the metals Cu, Ag, Zn, Cr, Mo, W, Co or Ni with a layer thickness of about 1 μm have been sputtered onto a glass plate.

On the respective rear contact, a layer with a composition of Zn_{0.99}Co_{0.01}Te has been sputtered with a layer thickness of about 1 μm using the target, which has been provided as described above.

For substituting tellurium by oxygen, the glass rear side of the layer structure, as produced above, has been put on a heating plate, which has been heated onto 350° C. for 5 minutes in air, and the surface temperature has been controlled by an infrared thermometer. After about 20 seconds, about 320 to 330° C. have been reached.

A blank sample without rear contact has been processed in the same way. The red blank sample changed its color nearly immediately to black, and in the XRD analysis, elementary tellurium has been detected, in addition to ZnTe.

The position of the band gaps has been measured using reflection-IR-spectroscopy and the following values have been provided:

| | Position of the intermediate | |
|---|---|---|
| Rear contact metal | band (eV) | Main band gap (eV) |
| Cu | 1.6 | 2.2 |
| Ag | 1.5 | 2.3 |
| Zn | 1.4 | 2.3 |
| Cr | 1.8 | 2.3 |
| Mo | 1.6 | 2.3 |
| W | 1.6 | 2.3 |
| Co | 1.6 | 2.3 |

### REFERENCE SIGNS

1 Substrate
2 Rear contact
3 p-conducting absorber layer
4 n-conducting layer
5 load
6 intermediate layer
7 photons
8 p-n junction
9 electron hole pairs

1-18. (canceled)

19. A photovoltaically active semiconductor material comprising a crystal lattice of zinc telluride, wherein ZnTe in the zinc telluride crystal lattice is replaced by
from 0.01 to 10 mol %,
from 0 to 10 mol % of Cu₂Te, Cu₃Te or CuTe and
from 0 to 30 mol % of at least one compound selected from the group consisting of MgTe and MnTe, wherein Te is substituted by 0.1 to 30 mol % oxygen.

20. The photovoltaically active semiconductor material according to claim 19, wherein Te in the zinc telluride crystal lattice is replaced by from 0 to 10 mol % of at least one element from the group consisting of N and P.

21. A photovoltaic cell comprising a photovoltaically active semiconductor material comprising a crystal lattice of zinc telluride, wherein ZnTe in the zinc telluride crystal lattice is replaced by
from 0.01 to 1.0 mol %,
from 0 to 10 mol % of Cu₂Te, Cu₃Te or CuTe and
from 0 to 30 mol % of at least one compound selected from the group consisting of MgTe and MnTe, wherein Te is substituted by 0.1 to 30 mol % oxygen,
wherein the photovoltaic cell further comprises a rear contact material, which forms, together with tellurium, a metal telluride.

22. The photovoltaic cell according to claim 21, wherein the rear contact material comprises at least one element selected from the group consisting of Cu, Ag, Zn, Cr, Mo, W, Co and Ni.

23. The photovoltaic cell according to claim 21, wherein Te in the zinc telluride crystal lattice is replaced by from 0 to 10 mol % of at least one element selected from the group consisting of N and P.

24. The photovoltaic cell according to claim 21, which comprises at least one p-conducting absorber layer of the photovoltaically active semiconductor material, wherein the absorber layer is arranged on the rear contact material.

25. The photovoltaic cell according to claim 21, comprising an n-conducting transparent layer which comprises at least one semiconductor material selected from the group consisting of indium-tin oxide, fluorine-doped tin oxide, antimony-doped zinc oxide, gallium-doped zinc oxide and aluminum-doped zinc oxide.

26. The photovoltaic cell according to claim 21, which comprises at least one p-conducting layer of the photovoltaically active semiconductor material, at least one n-conducting layer and a substrate which is a sheet of glass coated with an electrically conductive material, a flexible metal foil or a flexible metal sheet.

27. A process for producing a photovoltaically active semiconductor material according to claim 19 or a photovoltaic cell wherein a layer of the photovoltaically active semiconductor material of a material is produced, which forms together with tellurium, a metal telluride by means of at least one deposition process selected from the group consisting of sputtering, electrochemical deposition and electroless deposition, physical vapor deposition, chemical vapor deposition and laser ablation.

28. The process according to claim 27, wherein the production of the layer of the photovoltaically active semiconductor material is carried out in an oxygen containing atmosphere in order to replace the tellurium in the crystal lattice of the semiconductor material by oxygen.

29. The process according to claim 27, wherein a sputtering target comprising a photovoltaically active semiconductor material comprising a crystal lattice of zinc telluride in which ZnTe is replaced by
from 0.01 to 10 mol % of at least one compound selected from the group consisting of CoTe,
from 0 to 10 mol % of Cu₂Te, Cu₃Te or CuTe and
from 0 to 30 mol % of at least one compound selected from the group consisting of MgTe and MnTe,
is used for sputtering.

30. The process according to claim 27, wherein oxygen is introduced into the layer of the photovoltaically active semiconductor material by sputtering in a oxygen containing atmosphere.

31. The process according to claim 27, wherein nitrogen or phosphorus is introduced into the layer of the photovoltaically active semiconductor material by reactive sputtering in a nitrogen-, ammonia- or phosphine-comprising sputtering atmosphere.

32. The process according to claim 27, wherein copper is introduced into the layer of the photovoltaically active semiconductor material by cosputtering of a copper target with a target comprising the photovoltaically active semiconductor material.

33. The process according to claim 27, wherein a layer of the semiconductor material having a thickness of from 0.1 μm to 20 μm is produced.

34. The process according to claim 27, wherein a sputtering target comprising a crystal lattice of zinc telluride in which ZnTe is replaced by
from 0.01 to 10 mol % of CoTe,
from 0 to 10 mol % of Cu₂Te, Cu₃Te or CuTe and
from 0 to 30 mol % of at least one compound selected from the group consisting of MgTe and MnTe,
is produced by means of the steps
a) reaction of Zn, Te and Co and, if appropriate, Cu in an evacuated fused silica tube at from 800° C. to 1300° C. for a period of from 1 to 100 hours to give a material,
b) milling of the material after cooling with substantial exclusion of oxygen and water to give a powder having particle sizes of from 1 μm to 30 μm, and
c) hot pressing of the powder at temperatures of from 300° C. to 100° C. at pressures of from 5 to 500 MPa for pressing times of from 0.2 to 10 hours to give the sputtering target.

35. The process according to claim 27, comprising:
producing a layer of a semiconductor material comprising a crystal lattice of zinc telluride, wherein the ZnTe in the zinc telluride crystal lattice is substituted by 0.01 to 10 mol % CoTe, 0 to 10 mol % of Cu₂Te, Cu₃Te or CuTe and 0 to 30 mol % of at least one compound selected from the group consisting of MgTe and MnTe, and
maintaining the layer at a temperature between room temperature and 400° C. at an oxygen partial pressure of 0.01 Pa to 10⁵ Pa for a duration of between 0.1 and 100 min. for replacing tellurium in the crystal lattice of the semiconductor material by 0.1 to 30 mol % oxygen.

36. The process according to claim 27, wherein the layer of the photovoltaically active semiconductor material is maintained, subsequent to reaction conditions, under which a substitution of tellurium in the crystal lattice of the semiconductor material by oxygen occurs, at a temperature of between 250 and 350° C. in an inert atmosphere for a duration of between 0.1 to 10 min. for effecting a diffusion of tellurium in the semiconductor material, which forms, together with the tellurium, a metal telluride.
